(19) United States
(12) Patent Application Publication
(10) Pub. No.: US 2023/0060210 A1
(43) Pub. Date: Mar. 2, 2023

(54) SUBSTRATE TREATING APPARATUS

(71) Applicant: SEMES CO., LTD., Cheonan-si (KR)

(72) Inventors: Min Sung JEON, Osan-si (KR); Yun Sang KIM, Seongnam-si (KR); Sung Min CHOI, Osan-si (KR); Dong Young JANG, Seongnam-si (KR)

(73) Assignee: SEMES CO., LTD., Cheonan-si (KR)

(21) Appl. No.: 17/894,374

(22) Filed: Aug. 24, 2022

(30) Foreign Application Priority Data
Aug. 26, 2021 (KR) 10-2021-0113117

(51) Int. Cl. H01J 37/32

(52) U.S. Cl. CPC H01J 37/3255; H01J 37/32568; H01J 37/32541; H01J 37/32577; H01J 37/32522; H01J 2237/334

(57) ABSTRACT

The inventive concept provides a substrate treating apparatus. The substrate treating apparatus includes a chamber having a treating space therein; a support unit positioned within the treating space and configured to support a substrate; and a plasma generation unit configured to generate a plasma from a process gas supplied to the treating space, and wherein the plasma generation unit includes: a bottom electrode member and a top electrode member disposed opposite the bottom electrode, and wherein the top electrode member includes: a first plate; and an electrode pattern on the first plate and having a pattern.

### CROSS-REFERENCE TO RELATED APPLICATIONS

A claim for priority under 35 U.S.C. § 119 is made to Korean Patent Application No. 10-2021-0113117 filed on Aug. 26, 2021, in the Korean Intellectual Property Office, the entire contents of which are hereby incorporated by reference.

### BACKGROUND

Embodiments of the inventive concept described herein relate to a substrate treating apparatus for treating a substrate using a plasma.

In order to manufacture a semiconductor element, a desired pattern is formed on a substrate by performing various processes such as a photolithography process, an etching process, an ashing process, an ion implantation process, a thin film deposition process, and a cleaning process. Among them, the etching process is a process of removing a selected region from a film formed on the substrate, and a wet etching and a dry etching are used.

Among them, an etching device using a plasma is used for the dry etching. Generally, in order to form the plasma, an electromagnetic field is formed in an inner space of a chamber, and the electromagnetic field generates the plasma from a process gas provided in the chamber.

The plasma refers to an ionized gas state made of ions, electrons, or radicals. In a semiconductor element manufacturing process, the etching process is performed using the plasma.

### SUMMARY

Embodiments of the inventive concept provide a substrate treating apparatus which may perform a plasma treatment and a fast heating in one chamber, and which may improve an etching on a substrate or a uniformity of a film formation.

The technical objectives of the inventive concept are not limited to the above-mentioned ones, and the other unmentioned technical objects will become apparent to those skilled in the art from the following description.

The inventive concept provides a substrate treating apparatus. The substrate treating apparatus includes a chamber having a treating space therein; a support unit positioned within the treating space and configured to support a substrate; and a plasma generation unit configured to generate a plasma from a process gas supplied to the treating space, and wherein the plasma generation unit comprises: a bottom electrode member; a top electrode member disposed opposite the bottom electrode, and a high frequency power source for applying a high frequency power to the top electrode member, and wherein the top electrode member comprises: a first plate; and an electrode pattern on the first plate and including electrically insulated a first electrode pattern and a second electrode pattern.

In an embodiment, the high frequency power source is configured to supply a same frequency of high frequency power to the first electrode pattern and the second electrode pattern with a predetermined time interval.

In an embodiment, the high frequency power source comprises a first high frequency power source and a second high frequency power source which are configured to supply a different frequency of high frequency power to the first electrode pattern and the second electrode pattern.

In an embodiment, the electrode pattern is made of and/or includes a transparent electrode.

In an embodiment, the transparent electrode is formed of an ITO, an MnSnO, a CNT, a ZnO, an IZO, an ATO, an SnO₂, IrO₂, RuO₂, a graphene, a carbon nanotube (CNT), an AZO, an FTO, a GZO, an In₂O₃, an MgO, a conductive polymer, a metal nanowire, mixtures thereof, or multiple layers thereof.

In an embodiment, the first electrode pattern and the second electrode pattern comprises a bar-shaped connection portion and a plurality of pairs of semi-circular portions, respectively, adjacent pairs of semi-circular portions being spaced apart from each other, two semi-circular potions in a given pair of semi-circular portions extending from opposite sidewalls of the connection portion toward each other to define a gap therebetween, the connection portion of the first electrode pattern and the connection of the second electrode disposed in line such that the semi-circular portions of the first electrode pattern and the semi-circular portions of the second electrode pattern are alternatively arranged.

In an embodiment, the first electrode pattern and the second electrode pattern includes a plurality of line electrode segments arranged side by side.

In an embodiment, the first electrode pattern and the second electrode pattern includes a plurality of ring-shaped concentric electrodes, each ring-shaped electrode segment having arc portions spaced part from each other, and respective arc portions of the plurality of ring-shaped concentric electrodes being connected to each other by respective connection portion.

In an embodiment, the first plate is made of and/or includes a transparent material.

In an embodiment, the first plate is made of and/or includes a dielectric substance.

In an embodiment, the first plate is made of and/or includes a quartz material.

In an embodiment, a protective layer of an etching-resistant material is further provided at a surface of the first plate facing the treating space.

In an embodiment, the substrate treating apparatus further includes a heating unit positioned above the top electrode member and irradiating an energy through the top electrode member to the substrate to heat the substrate.

In an embodiment, the heating unit is any one of a flash lamp, a microwave unit, or a laser unit.

The inventive concept provides a substrate treating apparatus. The substrate treating apparatus includes a chamber having a treating space therein; a support unit positioned within the treating space and configured to support a substrate; and a plasma generation unit configured to generate a plasma from a process gas supplied to the treating space, and wherein the plasma generation unit includes: a bottom electrode member; a top electrode member disposed opposite the bottom electrode member; and a high frequency power source for applying a high frequency power to the top electrode member, and wherein the top electrode member includes: a first plate; and a plurality of electrode patterns stacked at the first plate and which do not overlap each other when seen from a plane, and wherein the high frequency power source includes a plurality of high frequency power sources for applying the high frequency power to at least one of the electrode patterns among the plurality of electrode patterns.

In an embodiment, the plurality of high frequency power sources are configured to supply a same frequency of high frequency power with a predetermined time interval.

In an embodiment, the plurality of high frequency power sources are configured to supply a different frequency of high frequency power.

In an embodiment, the electrode pattern is made of and/or comprises a transparent electrode.

In an embodiment, the transparent electrode is formed of any one of an ITO, an MnSnO, a CNT, a ZnO, an IZO, an ATO, an SnO₂, IrO₂, RuO₂, a graphene, a carbon nanotube (CNT), an AZO, an FTO, a GZO, an In₂O₃, an MgO, a conductive polymer, a metal nanowire, mixtures thereof, or multiple layers thereof.

The inventive concept provides a substrate treating apparatus. The substrate treating apparatus includes a chamber having a treating space therein; a support unit positioned within the treating space and configured to support a substrate; a plasma generation unit configured to generate a plasma from a process gas supplied to the treating space and including a bottom electrode member, a top electrode member positioned opposite from the bottom electrode member, and a high frequency power source applying a high frequency power to the top electrode member; and a heating unit positioned above the top electrode member and irradiating an energy for heating the substrate which transmits through an electrode member, and wherein the top electrode member includes: a first plate; and an electrode pattern on the first plate, composed of a transparent electrode, and including electrically insulated a first electrode pattern and a second electrode pattern, wherein a high frequency power supplied by the first high frequency power and a high frequency power supplied by the second high frequency power are supplied to have the same frequency and a time difference with respect to each other, or the high frequency power supplied by the first high frequency power and the high frequency power supplied by the second high frequency power are supplied to be different.

According to an embodiment of the inventive concept, an etching on a substrate or a uniformity of a film formation may be improved.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 illustrates a substrate treating apparatus according to an embodiment of the inventive concept.

FIG. 2 is a cross-sectional view illustrating a top electrode member according to an embodiment of the inventive concept.

FIG. 3 illustrates a pattern of an electrode pattern and a high frequency power source applied to the electrode pattern according to a first embodiment of the inventive concept.

FIG. 4 illustrates the pattern of the electrode pattern and the high frequency power source applied to the electrode pattern according to a second embodiment of the inventive concept.

FIG. 5 illustrates the pattern of the electrode pattern and the high frequency power source applied to the electrode pattern according to a third embodiment of the inventive concept.

FIG. 6 illustrates the pattern of the electrode pattern and the high frequency power source applied to the electrode pattern according to a fourth embodiment of the inventive concept.

### DETAILED DESCRIPTION

The inventive concept may be variously modified and may have various forms, and specific embodiments thereof will be illustrated in the drawings and described in detail. However, the embodiments according to the concept of the inventive concept are not intended to limit the specific disclosed forms, and it should be understood that the present inventive concept includes all transforms, equivalents, and replacements included in the spirit and technical scope of the inventive concept. In a description of the inventive concept, a detailed description of related known technologies may be omitted when it may make the essence of the inventive concept unclear.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises”, “comprising,”, “includes”, and/or “including” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “example” is intended to refer to an example or illustration.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

It should be understood that when an element or layer is referred to as being “on,” “connected to,” “coupled to,” or “covering” another element or layer, it may be directly on, connected to, coupled to, or covering the other element or layer or intervening elements or layers may be present. In contrast, when an element is referred to as being “directly on,” “directly connected to,” or “directly coupled to” another element or layer, there are no intervening elements or layers present. Other terms such as “between”, “adjacent”, “near” or the like should be interpreted in the same way.

Unless otherwise defined, all terms used herein, including technical or scientific terms, have the same meaning as those generally understood by those skilled in the art to which the inventive concept belongs. Terms such as those defined in commonly used dictionaries should be interpreted as consistent with the context of the relevant technology and not as ideal or excessively formal unless clearly defined in this application.

Hereinafter, a configuration represented by XXX-1, XXX-2, XXX-3, and XXX-n may be collectively referred to as XXX for convenience.

In an embodiment of the inventive concept, a substrate treating apparatus for etching a substrate using a plasma will be described. However, the technical characteristics of the inventive concept are not limited thereto, and may be applied to various types of apparatuses that treat the substrate W using the plasma. However, the inventive concept is not limited thereto, and may be applied to various types of apparatuses for plasma-treating a substrate placed on a top.

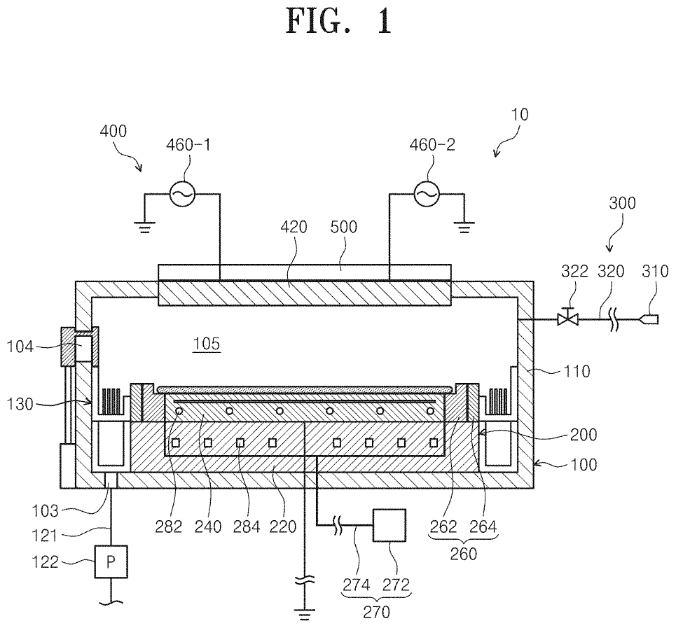

FIG. 1 illustrates a substrate treating apparatus according to an embodiment of the inventive concept.

Referring to FIG. 1, the substrate treating apparatus 10 may include a process chamber 100, a support unit 200, a gas supply unit 300, a plasma generation unit 400, and a heating unit 500. The substrate treating apparatus 10 treats a substrate W using a plasma.

The process chamber 100 has an inner space 105 for performing a process therein. An exhaust hole 103 is formed on a bottom surface of the process chamber 100. The exhaust hole 103 is connected to an exhaust line 121 on which a pump 122 is mounted. The reaction by-products generated during the process and a gas remaining in the process chamber 100 are exhausted to the exhaust hole 103 through the exhaust line 121. Accordingly, they may be discharged to an outside of the process chamber 100. In addition, an inner space 105 of the process chamber 100 is depressurized to a predetermined pressure by an exhaust process. In an embodiment, the exhaust hole 103 may be provided at a position directly connected to a through hole 158 of a liner unit 130 to be described later.

An opening 104 is formed at a sidewall of the process chamber 100. The opening 104 functions as a passage through which the substrate enters and exits the process chamber 100. The opening 104 is opened and closed by a door assembly. According to an embodiment, the door assembly has an outer door, an inner door, and a connection plate. The outer door is provided on an outer wall of the process chamber. The inner door is provided on an inner wall of the process chamber. The outer door and the inner door are fixedly coupled to each other by the connection plate. The connection plate is provided to extend from an inside to an outside of the process chamber through the opening. A door driver moves the outer door in an up/down direction. The door driver may include a pneumatic cylinder or a motor.

The support unit 200 is positioned at a bottom region of the inner space 105 of the process chamber 100. An electrostatic chuck unit may be provided as an embodiment of the support unit 200. The support unit 200 provided as the electrostatic chuck unit supports the substrate W by an electrostatic force. Unlike this, the support unit 200 may support the substrate W in various ways such as a mechanical clamping, a clamping by a vacuum, etc.

The support unit 200 may include an electrostatic chuck 240, a ring assembly 260, and a gas supply line unit 270. The substrate W is placed on a top surface of the electrostatic chuck 240. The electrostatic chuck 240 supports the substrate W on its top surface by an electrostatic force.

The ring assembly 260 is provided in a ring form. The ring assembly 260 is provided to surround a circumference of the support plate 210. In an embodiment, the ring assembly 260 is provided to surround a circumference of the electrostatic chuck 240. The ring assembly 260 supports an edge region of the substrate W. According to an embodiment, the ring assembly 260 has a focus ring 262 and an insulation ring 264. The focus ring 262 is provided to surround the electrostatic chuck 240 and focuses the plasma on the substrate W. The insulation ring 264 is provided to surround the focus ring 262. Selectively, the ring assembly 260 may include an edge ring (not shown) provided in close contact with a circumference of the focus ring 262 to prevent a side surface of the electrostatic chuck 240 from being damaged by the plasma. Unlike the above description, a structure of the ring assembly 260 may be variously changed.

The gas supply line unit 270 includes a gas supply source 272 and a gas supply line 274. The gas supply line 274 is provided between the ring assembly 260 and the support plate 210. The gas supply line 274 supplies a gas to remove foreign substances remaining on a top surface of the ring assembly 260 or an edge region of the support plate 210. In an embodiment, the gas may be a nitrogen gas N₂. Selectively, other gases or cleaning agents may be supplied. The gas supply line 274 may be formed to be connected between the focus ring 262 and the electrostatic chuck 240 in the support plate 210. Unlike this, the gas supply line 274 may be provided inside the focus ring 262 and bent to be connected between the focus ring 262 and the electrostatic chuck 240.

In an embodiment, the electrostatic chuck 240 may be provided as a ceramic material, the focus ring 262 may be provided as a silicone material, and the insulation ring 264 may be provided as a quartz material.

A heating member 282 may be provided inside the electrostatic chuck 240. The heating member 282 may be provided as a hot wire.

A bottom electrode member 440 forming the plasma generation unit 400 may be provided below the electrostatic chuck 240. A cooling means 284 for maintaining the substrate W at a process temperature during a process may be provided in the bottom electrode member 440. The cooling means 284 may be formed inside the bottom electrode member 440 and may be provided as a cooling fluid channel through which a refrigerant flows.

The gas supply unit 300 supplies a process gas to the inner space 105 of the process chamber 100. The gas supply unit 300 includes a gas storage unit 310 and a gas supply line 320. The gas supply line 320 connects the gas storage unit 310 to a gas inlet port of the process chamber 100. The gas supply line 320 supplies the process gas stored at the gas storage unit 310 to the inner space 105. A valve 322 for opening and closing a passage or for adjusting a flow rate of a fluid flowing through the passage may be installed at the gas supply line 320.

The plasma generation unit 400 generates a plasma from the process gas remaining in a discharge space. The discharge space corresponds to a top region of the support unit 200 in the process chamber 100. The plasma generation unit 400 may have a capacitive coupled plasma source.

The plasma generation unit 400 may include a top electrode member 420, a bottom electrode member 440, and a high frequency power source 460. The high frequency power may be provided as a plurality of high frequency powers. For example, the high frequency power 460 may include a first high frequency power 460-1 and a second high frequency power 460-2. The top electrode member 420 and the bottom electrode member 440 may be provided opposite to each other in the up/down direction. The bottom electrode 440 may be provided in the electrostatic chuck 240.

The plasma generation unit 400 according to an embodiment of the inventive concept may generate the plasma by applying an RF voltage to at least one of the top electrode member 420 and the bottom electrode member 440 in order to generate an electric field between the top electrode member 420 and the bottom electrode member 440.

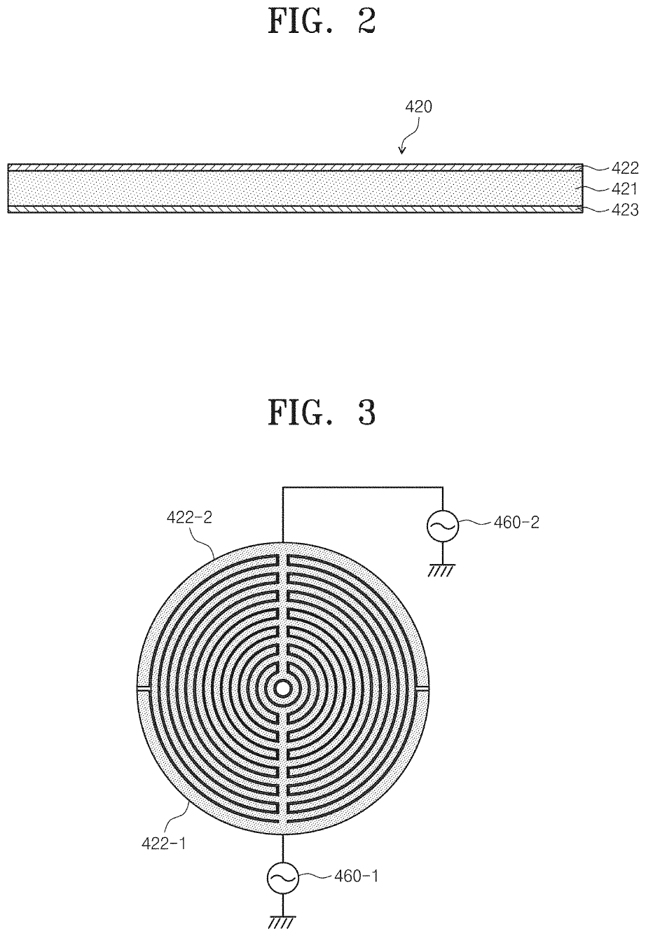

The top electrode member 420 according to an embodiment of the inventive concept may include a first plate 421 and an electrode pattern 422 so that an energy applied from the heating unit 500 to be described below may be transferred to the substrate without loss. The top electrode member 420 according to an embodiment of the inventive concept will be described later in FIG. 2 to FIG. 6.

According to an embodiment, the high frequency power source 460 may be connected to the top electrode member 420 and the bottom electrode member 440 may be grounded. In addition, the high frequency power source 460 may be selectively connected to both the top electrode member 420 and the bottom electrode member 440. According to an embodiment, the high frequency power source 460 may continuously apply a power to the top electrode member 420 or the bottom electrode member 440 or apply the power in pulses.

The heating unit 500 may transfer an energy to the substrate to heat the substrate on the support unit 200. The heating unit 500 may be a rapid thermal source. In an embodiment, a high-speed heat source may be provided as a flash lamp generating a flash light, a microwave unit generating a microwave, and a laser unit generating and transmitting a laser. The energy for heating the substrate may be selected as a flash light, a microwave, a laser, or the like.

In an embodiment, when the heating unit 500 is provided as a microwave unit, the heating unit 500 may apply the microwave to the substrate. For example, the heating unit 500 may apply microwaves having a frequency of 1 to 5 GHz. Since a wavelength of the microwave is much longer than a thickness and spacing of a metal wiring layer of a semiconductor chip, a depth at which the microwave penetrates into the metal material is less than several μm. According to an embodiment, a surface of the substrate or a die is heated by a microwave heat treatment, thereby rapidly increasing a surface temperature to a target temperature. When the substrate is heated by the microwave, only the surface of the substrate is selectively heated, and thus a heating speed and a cooling speed are fast, and the surface of the substrate may be heated to the target temperature within a short time, thereby reducing a process time.

Recently, an ALE is applied as an etching process. Atomic layer etching (ALE) is a method of removing a controlled amount of material, using an adsorption reaction that modifies a film surface and a desorption reaction that removes a modified film surface. Here, the adsorption reaction has a relatively high reactivity at a low temperature (e.g., room temperature), and the desorption reaction has a relatively high reactivity at a high temperature (e.g., 500 degrees Celsius or above). When an embodiment of the inventive concept is applied, a fast heating and a fast cooling are possible, and thus a temperature having a high reactivity in each of the adsorption reaction and desorption reaction may be applied.

According to an embodiment of the inventive concept, the energy such as the flash, the microwave, and the laser may pass through the top electrode member 420 to heat the substrate. The top electrode member 420 may be provided as a light-transmitting and microwave-transmitting material.

FIG. 2 is a cross-sectional view illustrating a top electrode member 420 according to an embodiment of the inventive concept. In the inventive concept, the top electrode member 420 including a transparent electrode 422 is proposed to improve a heat and a plasma uniformity of a substrate. The top electrode member 420 according to the inventive concept may include a first plate 421 and an electrode pattern 422 provided stacked at the first plate 421 in a conductive material. According to an embodiment, the electrode pattern 422 may be provided at a top surface of the first plate 421, so that it may be protected from an etching of the plasma. A protective layer 423 made of an etching-resistant material may be provided on a surface of the first plate 421 facing a treating space 105. The protective layer 423 may be provided in an etching-resistant material and may prevent an etching of a material in the plasma treatment process.

The electrode pattern 422 is connected to the high frequency power source 460.

The electrode pattern 422 may include a transparent electrode. According to an embodiment, the electrode pattern 422 may be a transparent electrode formed of an indium tin oxide (ITO) material made of an indium oxide and a tin oxide. In an embodiment, the electrode pattern 422 may be any one of an indium tin oxide (ITO), a manganese tin oxide (MnSnO), a carbon nano tube (CNT), a zinc oxide (ZO), an indium zinc oxide (ITO), an antimony tin oxide (NTO), an SnO₂, an IrO₂, an RuO₂, a dielectric/metal/dielectric multilayer (SnO₂/Ag/SnO₂), a graphene, an FTO (fluorine-doped tin oxide), an AZO (aluminum-doped zinc oxide), a GZO (gallium-doped zinc oxide), an In₂O₃, an MgO, a silver nanowire, or a conductive polymer. Also, it may be provided as a combination thereof. That is, the electrode pattern 422 may be formed of a transparent conductive material. Accordingly, a transmission factor of the energy for a heating described above may be increased.

The first plate 421 may serve as a dielectric window. The first plate 421 may be made of a material having a transparency. According to an embodiment, the first plate 421 may be provided as a quartz material. According to an embodiment, the first plate 421 may be an SiO₂.

According to an embodiment, the electrode pattern 422 included in the top electrode member 420, the first plate 421, and the protective layer 423 may be made of a transparent material so that the energy provided from the heating unit 500 passes through. According to an embodiment, the protective layer 423 may be provided as an etching-resistant material. In an embodiment, the protective layer 423 may be any one of an MgAl₂O₄, an Y₂O₃, a YSZ (yttria-stabilized zirconia, ZrO₂/Y₂O₃), a yttrium aluminum garnet (Y₃Al₅O₁₂), an Al₂O₃, a Cr₂O₃, a Nb₂O₅, a γ-AlON, or a SiN₃N₃. Alternatively, it may be provided as a mixture thereof. The protective layer 423 may be made of a material having a transparency, and a plasma resistance and an etching resistance.

FIG. 3 describes a pattern of an electrode pattern 422 and a high frequency power source 460 applied to the electrode pattern 422 according to a first embodiment of the inventive concept. The electrode pattern 422 includes a first electrode pattern 422-1 and a second electrode pattern 422-2. Each of the first electrode pattern 422-1 and the second electrode pattern 422-2 comprises a bar-shaped connection portion and a plurality of pairs of semi-circular portions, respectively, adjacent pairs of semi-circular portions being spaced apart from each other, two semi-circular potions in a given pair of semi-circular portions extending from opposite sidewalls of the connection portion toward each other to define a gap therebetween, the connection portion of the first electrode pattern and the connection of the second electrode disposed in line such that the semi-circular portions of the first electrode pattern and the semi-circular portions of the second electrode pattern are alternatively arrange. The first electrode pattern 422-1 and the second electrode pattern 422-2 are alternately disposed without overlapping each other. A first high frequency power source 460-1 is connected to the first electrode pattern 422-1. The first high frequency power source 460-1 applies a first high frequency power to the first electrode pattern 422-1. A second high frequency power source 460-2 is connected to the second electrode pattern 422-2. The second high frequency power source 460-2 applies a second high frequency power to the second electrode pattern 422-2. The first high-frequency power source 460-1 and the second high-frequency power source 460-2 may supply a power of the same frequency and with a predetermined time interval, and apply a high-frequency power to the first electrode pattern 422-1 and the second electrode pattern 422-2. Having a predetermined time interval means a shifting of a phase of the high frequency power. As another example, the first high frequency power source 460-1 and the second high frequency power source 460-2 may supply a power of different frequencies. For example, a frequency may be 13.56, 12.56, 13.96 MHz, or the like. A high-frequency power with a predetermined time interval is applied to each of the first electrode pattern 422-1 and the second electrode pattern 422-2 or high-frequency powers which are different from each other are each applied to the first electrode pattern 422-1 and the second electrode pattern 422-2, thereby avoiding an influence of a harmonic resonance and controlling a generation of a plasma. A plasma uniformity may be improved by controlling the generation of the plasma.

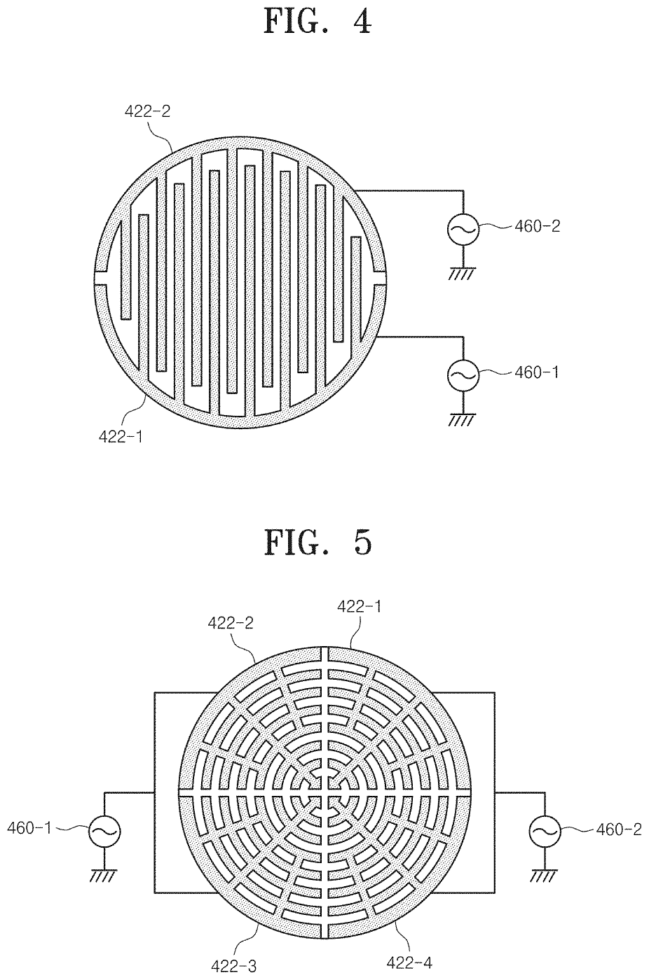

FIG. 4 illustrates a pattern of an electrode pattern 422 and a high frequency power source 460 applied to the electrode pattern 422 according to a second embodiment of the inventive concept. The electrode pattern 422 includes a first electrode pattern 422-1 and a second electrode pattern 422-2. The first electrode pattern 422-1 and the second electrode pattern 422-2 are formed in a linear combination arranged side by side. The pattern forming the electrode pattern 422 is formed by arranging the first electrode pattern 422-1 and the second electrode pattern 422-2 alternately without overlapping each other. A first high frequency power source 460-1 is connected to the first electrode pattern 422-1. A second high frequency power source 460-2 is connected to the second electrode pattern 422-2. The first high-frequency power source 460-1 and the second high-frequency power source 460-2 may supply a power of the same frequency and may have a predetermined time interval, and apply a high-frequency power to the first electrode pattern 422-1 and the second electrode pattern 422-2. Having a predetermined time interval means a shifting of a phase of the high frequency power. As another example, the first high frequency power source 460-1 and the second high frequency power source 460-2 may supply a power of different frequencies. For example, a frequency may be 13.56, 12.56, 13.96 MHz, or the like. The high-frequency power having the predetermined time interval is applied to each of the first electrode pattern 422-1 and the second electrode pattern 422-2 or high-frequency powers which are different from each other are each applied to the first electrode pattern 422-1 and the second electrode pattern 422-2, thereby avoiding an influence of a harmonic resonance and controlling a generation of a plasma. A plasma uniformity may be improved by controlling the generation of the plasma.

FIG. 5 describes a pattern of an electrode pattern 422 and a high frequency power source 460 applied to the electrode pattern 422 according to a third embodiment of the inventive concept. The electrode pattern 422 includes a first electrode pattern 422-1, a second electrode pattern 422-2, a third electrode pattern 422-3, and a fourth electrode pattern 422-4. The electrode pattern 422 may include a combination of a plurality of arc forms forming a plurality of ring forms and a plurality of connection lines connecting the plurality of arc forms. In other words, the first electrode pattern 422-1, the second electrode pattern 422-2, the third electrode pattern 422-3, and the fourth electrode pattern 422-4 are each formed of a combination of a plurality of arc forms having different radii and a connection line connecting them. A first high frequency power source 460-1 is connected to the second electrode pattern 422-2 and the third electrode pattern 422-3. A second high frequency power source 460-2 is connected to the first electrode pattern 422-1 and the fourth electrode pattern 422-4. The first high-frequency power source 460-1 and the second high-frequency power source 460-2 may supply a power of the same frequency and may have a predetermined time interval, and apply a high-frequency power to the first electrode pattern 422-1 and the second electrode pattern 422-2. Having a predetermined time interval means a shifting of a phase of the high frequency power. As another example, the first high frequency power source 460-1 and the second high frequency power source 460-2 may supply a power of different frequencies. For example, a frequency may be 13.56, 12.56, 13.96 MHz, or the like. The high-frequency power having the predetermined time interval is applied to each of the first electrode pattern 422-1 and the second electrode pattern 422-2 or high-frequency powers which are different from each other are each applied to the first electrode pattern 422-1 and the second electrode pattern 422-2, thereby avoiding an influence of a harmonic resonance and controlling a generation of a plasma. By controlling the generation of the plasma, it is possible to improve a uniformity of an etching or a film formation on the substrate.

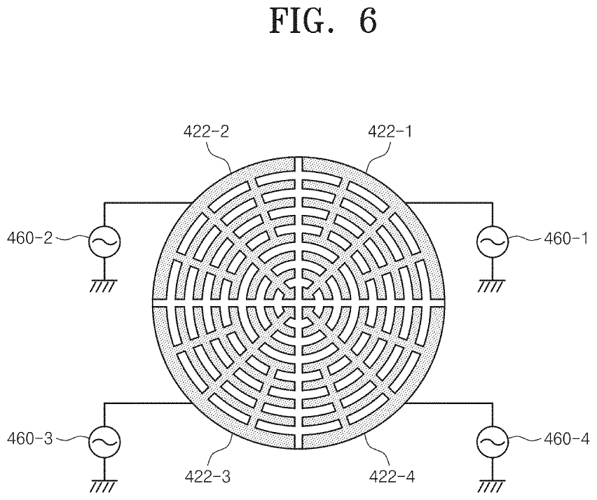

FIG. 6 describes a pattern of an electrode pattern 422 and a high frequency power source 460 applied to the electrode pattern 422 according to a fourth embodiment of the inventive concept. The electrode pattern 422 includes a first electrode pattern 422-1, a second electrode pattern 422-2, a third electrode pattern 422-3, and a fourth electrode pattern 422-4. The electrode pattern 422 may include a combination of a plurality of arc forms forming a plurality of ring forms and a plurality of connection lines connecting the arcs. In other words, the first electrode pattern 422-1, the second electrode pattern 422-2, the third electrode pattern 422-3, and the fourth electrode pattern 422-4 are each formed of a combination of a plurality of arc forms having a different radii and a connection line connecting them. A first high frequency power source 460-1 is connected to the first electrode pattern 422-1. A second high frequency power source 460-2 is connected to the second electrode pattern 422-2. A third high frequency power source 460-3 is connected to the third electrode pattern 422-3. A fourth high frequency power source 460-4 is connected to the fourth electrode pattern 422-4. The first high-frequency power source 460-1, the second high-frequency power source 460-2, the third high-frequency power source 4603, and the fourth high-frequency power source 460-4 may supply a power of the same frequency but may have a predetermined time interval, and apply a high-frequency power to each electrode pattern 422. Having a predetermined time interval means a shifting of a phase of the high frequency power. The predetermined time interval can be clockwise, counterclockwise, or diagonal. As another example, the first high frequency power source 460-1, the second high frequency power source 460-2, the third high frequency power source 460-3 and the fourth high frequency power source 460-4 may supply a power of different frequencies. For example, a frequency may be 13.56, 12.56, 13.96 MHz, or the like. The high frequency power having the predetermined time interval is applied to each of the electrode patterns 422 or high frequency powers which are different from each other are applied to each of the electrode patterns 422, thereby avoiding an influence of a harmonic resonance and controlling a generation of a plasma. By controlling the generation of the plasma, it is possible to improve a uniformity of an etching or a film formation on the substrate.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

What is claimed is:

1. A substrate treating apparatus comprising:
a chamber having a treating space therein;
a support unit positioned within the treating space and configured to support a substrate; and
a plasma generation unit configured to generate a plasma from a process gas supplied to the treating space, and
wherein the plasma generation unit comprises:
a bottom electrode member;
a top electrode member disposed opposite the bottom electrode, and
a high frequency power source for applying a high frequency power to the top electrode member, and
wherein the top electrode member comprises:
a first plate; and
an electrode pattern on the first plate and including electrically insulated a first electrode pattern and a second electrode pattern.

2. The substrate treating apparatus of claim 1, wherein the high frequency power source is configured to supply a same frequency of high frequency power to the first electrode pattern and the second electrode pattern with a predetermined time interval.

3. The substrate treating apparatus of claim 1, wherein the high frequency power source comprises a first high frequency power source and a second high frequency power source which are configured to supply a different frequency of high frequency power to the first electrode pattern and the second electrode pattern.

4. The substrate treating apparatus of claim 1, wherein the electrode pattern is made of and/or comprises a transparent electrode.

5. The substrate treating apparatus of claim 4, wherein the transparent electrode is formed of an ITO, an MnSnO, a CNT, a ZnO, an IZO, an ATO, an SnO₂, IrO₂, RuO₂, a graphene, a carbon nanotube (CNT), an AZO, an FTO, a GZO, an In₂O₃, an MgO, a conductive polymer, a metal nanowire, mixtures thereof, or multiple layers thereof.

6. The substrate treating apparatus of claim 1, wherein the first electrode pattern and the second electrode pattern comprises a bar-shaped connection portion and a plurality of pairs of semi-circular portions, respectively, adjacent pairs of semi-circular portions being spaced apart from each other, two semi-circular potions in a given pair of semi-circular portions extending from opposite sidewalls of the connection portion toward each other to define a gap therebetween, the connection portion of the first electrode pattern and the connection of the second electrode disposed in line such that the semi-circular portions of the first electrode pattern and the semi-circular portions of the second electrode pattern are alternatively arranged.

7. The substrate treating apparatus of claim 1, wherein the first electrode pattern and the second electrode pattern comprises a plurality of line electrode segments arranged side by side.

8. The substrate treating apparatus of claim 1, wherein the first electrode pattern and the second electrode pattern comprises a plurality of ring-shaped concentric electrodes, each ring-shaped electrode segment having arc portions spaced part from each other, and respective arc portions of the plurality of ring-shaped concentric electrodes being connected to each other by respective connection portion.

9. The substrate treating apparatus of claim 1, wherein the first plate is made of and/or comprises a transparent material.

10. The substrate treating apparatus of claim 1, wherein the first plate is made of and/or comprises a dielectric substance.

11. The substrate treating apparatus of claim 1, wherein the first plate is made of and/or comprises a quartz material.

12. The substrate treating apparatus of claim 1, wherein a protective layer of an etching-resistant material is further provided at a surface of the first plate facing the treating space.

13. The substrate treating apparatus of claim 1, further comprising a heating unit positioned above the top electrode member and irradiating an energy through the top electrode member to the substrate to heat the substrate.

14. The substrate treating apparatus of claim 13, wherein the heating unit is any one of a flash lamp, a microwave unit, or a laser unit.

15. A substrate treating apparatus comprising:
a chamber having a treating space therein;
a support unit positioned within the treating space and configured to support a substrate; and
a plasma generation unit configured to generate a plasma from a process gas supplied to the treating space, and
wherein the plasma generation unit comprises:
a bottom electrode member;
a top electrode member disposed opposite the bottom electrode member; and
a high frequency power source for applying a high frequency power to the top electrode member, and
wherein the top electrode member comprises:
a first plate; and
a plurality of electrode patterns stacked at the first plate and which do not overlap each other when seen from a plane, and
wherein the high frequency power source includes a plurality of high frequency power sources for applying the high frequency power to at least one of the electrode patterns among the plurality of electrode patterns.

16. The substrate treating apparatus of claim 15, wherein the plurality of high frequency power sources are configured to supply a same frequency of high frequency power with a predetermined time interval.

17. The substrate treating apparatus of claim 15, where the plurality of high frequency power sources are configured to supply a different frequency of high frequency power.

18. The substrate treating apparatus of claim 15, wherein the electrode pattern is made of and/or comprises a transparent electrode.

19. The substrate treating apparatus of claim 18, wherein the transparent electrode is formed of any one of an ITO, an MnSnO, a CNT, a ZnO, an IZO, an ATO, an SnO₂, IrO₂, RuO₂, a graphene, a carbon nanotube (CNT), an AZO, an FTO, a GZO, an In₂O₃, an MgO, a conductive polymer, a metal nanowire, mixtures thereof, or multiple layers thereof.

20. A substrate treating apparatus comprising:
a chamber having a treating space therein;
a support unit positioned within the treating space and configured to support a substrate;
a plasma generation unit configured to generate a plasma from a process gas supplied to the treating space and including a bottom electrode member, a top electrode member positioned opposite from the bottom electrode member, and a high frequency power source applying a high frequency power to the top electrode member; and
a heating unit positioned above the top electrode member and irradiating an energy for heating the substrate which transmits through an electrode member, and
wherein the top electrode member comprises:
a first plate; and
an electrode pattern on the first plate, composed of a transparent electrode, and including electrically insulated a first electrode pattern and a second electrode pattern,
wherein a high frequency power supplied by the first high frequency power and a high frequency power supplied by the second high frequency power are supplied to have the same frequency and a time difference with respect to each other, or the high frequency power supplied by the first high frequency power and the high frequency power supplied by the second high frequency power are supplied to be different.
